(19) United States
(12) Patent Application Publication
(10) Pub. No.: US 2023/0377851 A1
(43) Pub. Date: Nov. 23, 2023

(54) ETCHING METHOD AND PLASMA PROCESSING APPARATUS

(71) Applicant: Tokyo Electron Limited, Tokyo (JP)

(72) Inventors: Fumiya YOSHII, Kurokawa-gun (JP); Kenji KOMATSU, Kurokawa-gun (JP)

(73) Assignee: Tokyo Electron Limited, Tokyo (JP)

(21) Appl. No.: 18/319,419

(22) Filed: May 17, 2023

(30) Foreign Application Priority Data
May 20, 2022 (JP) 2022-082922

(51) Int. Cl. H01J 37/32; H01L 21/311

(52) U.S. Cl. CPC H01J 37/32449; H01L 21/31116; H01J 2237/334

(57) ABSTRACT

An etching method includes (a) providing a substrate on a substrate support in a chamber, the substrate including a first region having a multilayer film in which a silicon oxide film and a silicon nitride film are alternately stacked, a second region having a single-layer silicon oxide film, and a mask; (b) etching the substrate with a first plasma generated from a first process gas; and (c) etching the substrate with a second plasma generated from a second process gas different from the first process gas. The first process gas contains a Cᵥ₁F_{w1} (v1 is an integer of 2 or more, and w1 is an integer of 1 or more) gas containing an unsaturated bond. The second process gas contains a Cₓ₁H_{y1}F_{z1} (x1 is an integer of 2 or more, and y1 and z1 are integers of 1 or more) gas containing an unsaturated bond.

### CROSS-REFERENCE TO RELATED APPLICATIONS

This application is based on and claims the benefit of priority from Japanese Patent Application No. 2022-082922 filed on May 20, 2022, the entire contents of which are incorporated herein by reference.

### FIELD

Exemplary embodiments of the present disclosure relate to an etching method and a plasma processing apparatus.

### BACKGROUND

Japanese Unexamined Patent Publication No. 2016-51750 discloses a method of etching a first region having a multilayer film formed by alternately providing a silicon oxide film and a silicon nitride film and a second region having a single-layer silicon oxide film. According to the etching method disclosed in Japanese Unexamined Patent Publication No. 2016-51750, a step of generating a plasma of a first process gas containing hydrofluorocarbon and a step of generating a plasma of a second process gas containing fluorocarbon are repeated alternately.

### SUMMARY

In an exemplary embodiment, an etching method includes (a) providing a substrate on a substrate support in a chamber, the substrate including a first region having a multilayer film in which a silicon oxide film and a silicon nitride film are alternately stacked, a second region having a single-layer silicon oxide film, and a mask on the first region and the second region; (b) etching the substrate with a first plasma generated from a first process gas; and (c) etching the substrate with a second plasma generated from a second process gas different from the first process gas, wherein the first process gas contains a Cᵥ₁F_{w1} (v1 is an integer of 2 or more, and w1 is an integer of 1 or more) gas containing an unsaturated bond, and the second process gas contains a Cₓ₁H_{y1}F_{z1} (x1 is an integer of 2 or more, and y1 and z1 are integers of 1 or more) gas containing an unsaturated bond.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a schematic diagram illustrating a plasma processing apparatus according to an exemplary embodiment.

FIG. 2 is a schematic diagram illustrating the plasma processing apparatus according to an exemplary embodiment.

FIG. 3 is a flowchart illustrating an etching method according to an exemplary embodiment.

FIG. 4 is a cross-sectional view of an example substrate to which the method of FIG. 3 can be applied.

FIG. 5 is a cross-sectional view of an example substrate after the method of FIG. 3 has been applied.

FIG. 6 is a cross-sectional view of a substrate having a recess having an example aspect ratio.

### DETAILED DESCRIPTION

Hereinafter, various exemplary embodiments (1) to (18) will be described.

(1) An etching method includes (a) providing a substrate on a substrate support in a chamber, the substrate including a first region having a multilayer film in which a silicon oxide film and a silicon nitride film are alternately stacked, a second region having a single-layer silicon oxide film, and a mask on the first region and the second region; (b) etching the substrate with a first plasma generated from a first process gas; and (c) etching the substrate with a second plasma generated from a second process gas different from the first process gas, wherein the first process gas contains a Cᵥ₁F_{w1} (v1 is an integer of 2 or more, and w1 is an integer of 1 or more) gas containing an unsaturated bond, and the second process gas contains a Cₓ₁H_{y1}F_{z1} (x1 is an integer of 2 or more, and y1 and z1 are integers of 1 or more) gas containing an unsaturated bond.

According to the above etching method, it is possible to improve etching selectivity of the first region and the second region with respect to the mask. Although the mechanism is considered as follows, the mechanism is not limited to this. In (b) and (c), higher-order radicals are generated from unsaturated bonds contained in the first process gas and the second process gas, respectively. Higher-order radicals have high molecular weights, so the higher-order radicals tend to form a deposited film on the surface of the mask. As a result, it is possible to improve the etching selectivity of the first region and the second region with respect to the mask.

(2) In the above (1), the etching method may further include (d) repeating (b) and (c) alternately. In this case, it is possible to increase the depth of a recess formed in the first region and the depth of a recess formed in the second region.

(3) In the above (1) or (2), the first process gas may further contain a Cₓ₂H_{y2}F_{z2} (x2 is an integer of 2 or more, and y2 and z2 are integers of 1 or more) gas containing an unsaturated bond, and the second process gas may further contain a Cᵥ₂F_{w2} (v2 is an integer of 2 or more, and w2 is an integer of 1 or more) gas containing an unsaturated bond, and a ratio of a flow rate of the Cᵥ₁F_{w1} gas to a flow rate of the Cₓ₂H_{y2}F_{z2} gas may be greater than a ratio of a flow rate of the Cᵥ₂F_{w2} gas to a flow rate of the Cₓ₁H_{y1}F_{z1} gas.

A fluorocarbon gas has an etching rate with respect to a silicon oxide film, which is higher than an etching rate with respect to a silicon nitride film. Hydrofluorocarbon has an etching rate with respect to the silicon nitride film, which is higher than an etching rate with respect to the silicon oxide film. Thus, in (b), the second region is preferentially etched over the first region. In (c), the first region is preferentially etched over the second region.

(4) In the above (3), the ratio of the flow rate of the Cᵥ₁F_{w1} gas to the flow rate of the Cₓ₂H_{y2}F_{z2} gas may be 1 or more and 2 or less.

(5) In the above (3) or (4), the ratio of the flow rate of the Cᵥ₂F_{w2} gas to the flow rate of the Cₓ₁H_{y1}F_{z1} gas may be less than 1.

(6) In any one of the above (1) to (5), the Cᵥ₁F_{w1} gas may contain a fluoromethyl group. In this case, in (b), a lower-order radical is generated from the fluoromethyl group. Since the lower-order radicals have low molecular weights, the lower-order radicals can go deep into a recess formed by etching. Thus, it is possible to form a deep recess by etching.

(7) In the above (6), the Cᵥ₁F_{w1} gas may contain at least one of C₄F₈ or C₃F₆.

(8) In any one of the above (1) to (7), the Cₓ₁H_{y1}F_{z1} gas may contain a fluoromethyl group. In this case, in (c), lower-order radicals are generated from the fluoromethyl group. Since the lower-order radicals have low molecular weights, the lower-order radicals can go deep into a recess formed by etching. Thus, it is possible to form a deep recess by etching.

(9) In the above (8), the Cₓ₁H_{y1}F_{z1} gas may contain at least one of C₃H₂F₄ or C₄H₂F₆.

(10) In any one of the above (1) to (7), the Cᵥ₁F_{w1} gas may contain C₃F₆, and the Cₓ₁H_{y1}F_{z1} gas may contain C₃H₂F₄.

(11) In any one of the above (1) to (10), a pressure in the chamber in (b) may be higher than a pressure in the chamber in (c).

(12) In any one of the above (1) to (11), a processing time of (b) may be longer than a processing time of (c).

(13) In the above (12), a ratio of the processing time of (b) to the processing time of (c) may be more than 1 and 3 or less.

(14) In any one of the above (1) to (13), wherein an aspect ratio of a recess formed in the first region and an aspect ratio of a recess formed in the second region in the substrate after the etching method has been applied may be equal to or more than 10.

(15) In any one of the above (1) to (14), at least one of the first process gas or the second process gas may further contain an oxygen-containing gas.

(16) In any one of the above (1) to (15), wherein at least one of the first process gas or the second process gas may further contain an inert gas.

(17) In any one of the above (1) to (16), the mask may contain at least one of carbon or boron.

(18) A plasma processing apparatus includes a chamber; a substrate support for supporting a substrate in the chamber, the substrate including a first region having a multilayer film in which a silicon oxide film and a silicon nitride film are alternately stacked, a second region having a single-layer silicon oxide film, and a mask on the first region and the second region; a gas supply configured to supply a first process gas and a second process gas different from the first process gas into the chamber; a plasma generator configured to generate a first plasma and a second plasma from the first process gas and the second process gas in the chamber, respectively; and a controller, wherein the first process gas contains a Cᵥ₁F_{w1} (v1 is an integer of 2 or more, and w1 is an integer of 1 or more) gas containing an unsaturated bond, the second process gas contains a Cₓ₁H_{y1}F_{z1} (x1 is an integer of 2 or more, and y1 and z1 are integers of 1 or more) gas containing an unsaturated bond, and the controller is configured to control the gas supply and the plasma generator to etch the substrate with the first plasma, and etch the substrate with the second plasma.

Hereinafter, various exemplary embodiments will be described in detail with reference to the drawings. In the drawing, the same or equivalent portions are denoted by the same reference symbols.

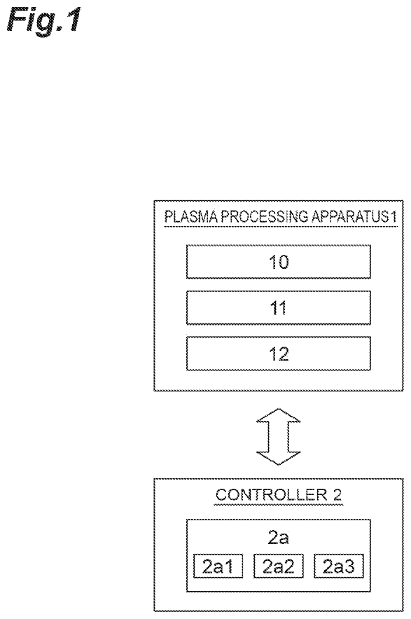

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

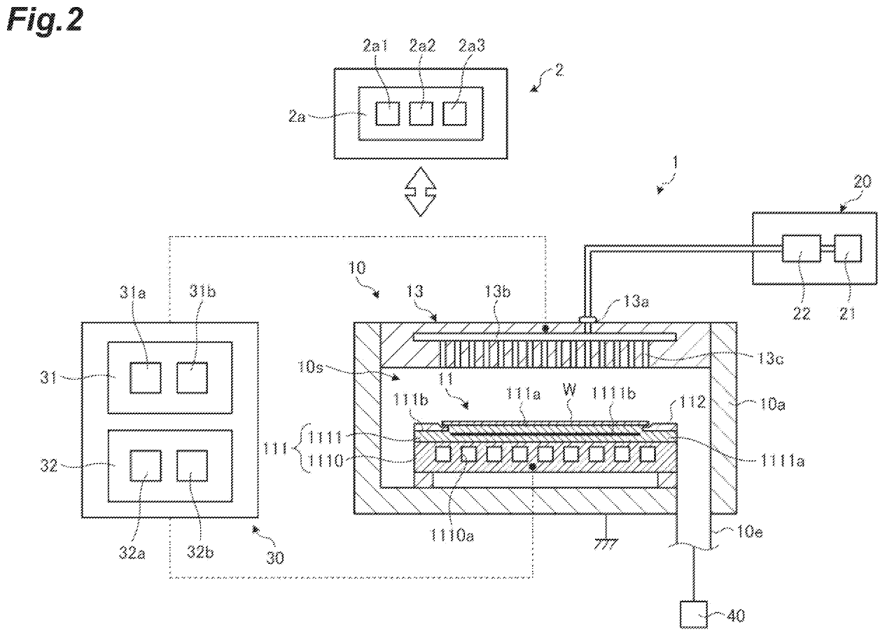

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate V and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

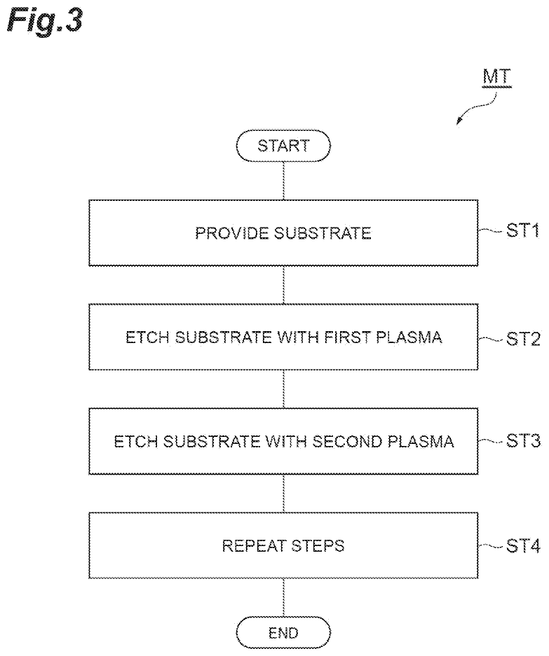

FIG. 3 is a flowchart illustrating an etching method according to an exemplary embodiment. An etching method MT (referred to as a “method MT” below) illustrated in FIG. 3 can be performed by the plasma processing apparatus 1 in the above embodiment. The method MT can be applied to a substrate W.

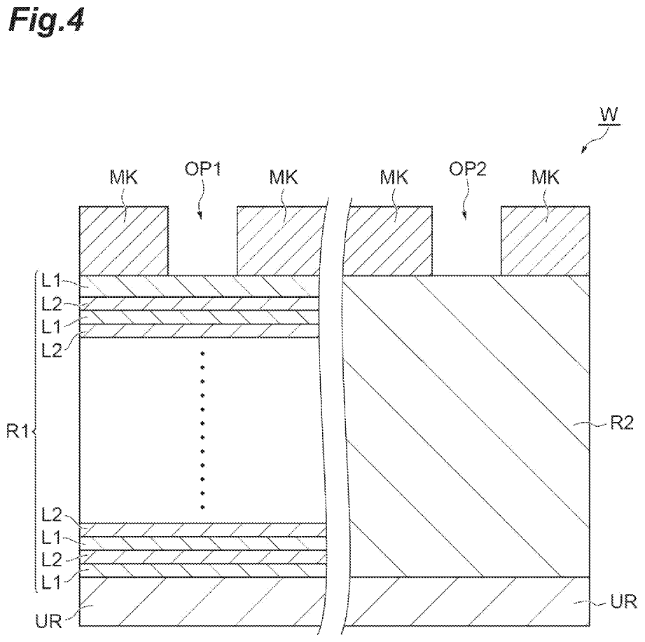

FIG. 4 is a cross-sectional view of an example substrate to which the method of FIG. 3 can be applied. As illustrated in FIG. 4, in the embodiment, the substrate W includes a first region R1, a second region R2, and a mask MK. The mask MK is on the first region R1 and the second region R2. The substrate W may include an underlying region UR. The first region R1 and the second region R2 may be provided on the underlying region UR.

The first region R1 has a multilayer film in which silicon oxide films L1 and silicon nitride films L2 are alternately stacked. The silicon oxide film L1 may be located on each of the top surface and the bottom surface of the first region R1. The second region R2 has a single-layer silicon oxide film. The first region R1 and the second region R2 may be arranged in a direction along the main surface of the substrate W. In a direction perpendicular to the main surface of the substrate W, the first region R1 may have the same thickness as the second region R2. Each of the first region R1 and the second region R2 may be a film for a memory device such as a 3D-NAND.

The mask MK may have an opening OP1 over the first region R1 and an opening OP2 over the second region R2. The mask MK may contain at least one of carbon or boron. The mask MK may contain at least one of spin-on carbon, tungsten carbide, or amorphous carbon. The mask MK may contain at least one of boron nitride or boron carbide.

The underlying region UR may contain at least one of silicon, organic (carbon-containing) material, or metal.

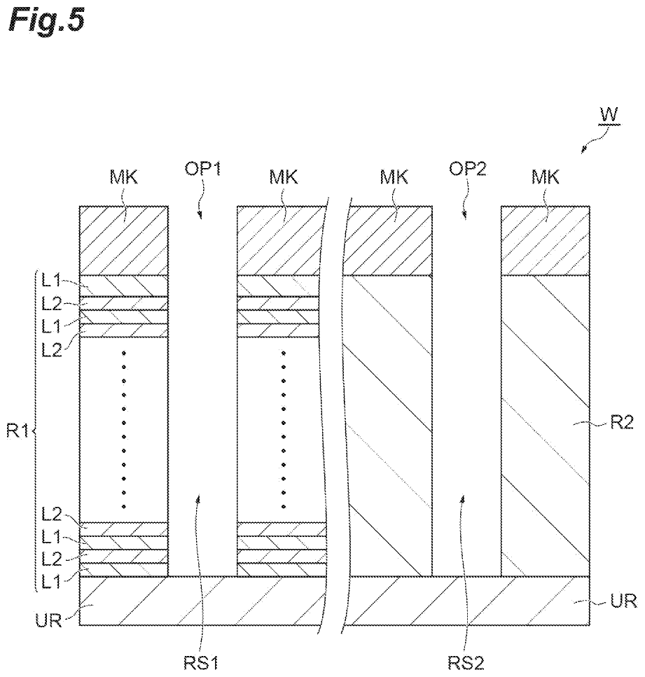

The method MT will be described with reference to FIGS. 3 to 5 by using, as an example, the case where the method MT is applied to the substrate W by using the plasma processing apparatus 1 in the above-described embodiment. FIG. 5 is a cross-sectional view of an example substrate after the method of FIG. 3 has been applied. When the plasma processing apparatus 1 is used, the method MT can be performed in the plasma processing apparatus 1 in a manner that the controller 2 controls each unit of the plasma processing apparatus 1. In the method MT, as illustrated in FIG. 2, the substrate W on a substrate support 11 disposed in a plasma processing chamber 10 is processed.

As illustrated in FIG. 3, the method MT can include Steps ST1 to ST4. Steps ST1 to ST4 can be performed in order. The method MT may not include Step ST4. Step ST3 may be performed before Step ST2.

In Step ST1, the substrate W illustrated in FIG. 4 is on the substrate support 11 in the plasma processing chamber 10. The underlying region UR can be disposed between the first region R1 or the second region R2, and the substrate support 11.

In Step ST2, the substrate W is etched with a first plasma generated from a first process gas. By etching the first region R1, a recess corresponding to the opening OP1 of the mask MK can be formed in the first region R1. By etching the second region R2, a recess corresponding to the opening OP2 of the mask MK can be formed in the second region R2.

The first process gas contains a Cᵥ₁F_{w1} (v1 is an integer of 2 or more, and w1 is an integer of 1 or more) gas containing an unsaturated bond. The Cᵥ₁F_{w1} gas is a fluorocarbon gas. The unsaturated bond may include a carbon double bond or a carbon triple bond. The Cᵥ₁F_{w1} gas may contain a plurality of unsaturated bonds. The Cᵥ₁F_{w1} gas may contain a fluorine substituent. The Cᵥ₁F_{w1} gas may contain a fluoromethyl group (—CFₓ). The Cᵥ₁F_{w1} gas may contain a plurality of fluoromethyl groups. The fluoromethyl group may be a monofluoromethyl group, a difluoromethyl group, or a trifluoromethyl group. The Cᵥ₁F_{w1} gas may contain at least one of C₄F₈ or C₃F₆. Each of C₄F₈ and C₃F₆ contains one double bond and one trifluoromethyl group.

The first process gas may further contain a Cₓ₂H_{y2}F_{z2} (x2 is an integer of 2 or more, and y2 and z2 are integers of 1 or more) gas containing an unsaturated bond. The Cₓ₂H_{y2}F_{z2} gas is a hydrofluorocarbon gas. The unsaturated bond may include a carbon double bond or a carbon triple bond. The Cₓ₂H_{y2}F_{z2} gas may contain a plurality of unsaturated bonds. The Cₓ₂H_{y2}F_{z2} gas may contain a fluorine substituent. The Cₓ₂H_{y2}F_{z2} gas may contain a fluoromethyl group (—CFₓ). The Cₓ₂H_{y2}F_{z2} gas may contain a plurality of fluoromethyl groups. The fluoromethyl group may be a monofluoromethyl group, a difluoromethyl group, or a trifluoromethyl group. The Cₓ₂H_{y2}F_{z2} gas may contain at least one of C₃H₂F₄ or C₄H₂F₆. Each of C₃H₂F₄ and C₄H₂F₆ contains one double bond and one trifluoromethyl group.

The first process gas may contain a C₃F₆ gas as the Cᵥ₁F_{w1} gas and a C₃H₂F₄ gas as the Cₓ₂H_{y2}F_{z2} gas. A ratio RT1 of the flow rate of the Cᵥ₁F_{w1} gas to the flow rate of the Cₓ₂H_{y2}F_{z2} gas may be 1 or more and 2 or less.

The first process gas may further contain an oxygen-containing gas. The oxygen-containing gas may contain at least one of a CO gas, a COS gas, or an O₂ gas. The first process gas may further contain an inert gas. The inert gas may contain at least one of a noble gas such as Ar or a N₂ gas.

The first plasma may be generated at a first pressure. The first pressure may be the pressure in the plasma processing chamber 10. A first radio frequency power may be supplied to generate the first plasma. The first radio frequency power may be an RF power HF applied to an upper electrode of the plasma processing apparatus 1. In Step ST2, bias power LF may be applied to electrodes in a body 111 of the substrate support 11. The bias power LF may be 10 kW or more.

In Step ST2, both the RF power HF and the bias power LF may be supplied periodically. The period during which the RF power HF is supplied may be synchronized with the period during which the bias power LF is supplied. The frequency for defining the period during which the RF power HF is supplied may be 1 kHz or greater and 10 kHz or smaller, or may be 1 kHz or greater and 5 kHz or smaller. In this case, the Duty ratio indicating the ratio of the supply time of the RF power HF within one period may be 10% or more and 90% or less, 20% or more and 80% or less, or 30% or more and 80% or less. By controlling the frequency and the Duty ratio of the RF power HF within the above range, it is possible to suppress plasma dissociation and increase the generated amount of higher-order radicals.

The processing time of Step ST2 may be 10 seconds or greater and 100 seconds or smaller.

Step ST2 may be performed as follows. First, a gas supply 20 supplies the first process gas into the plasma processing chamber 10. Then, a plasma generator 12 generates the first plasma from the first process gas in the plasma processing chamber 10. The controller 2 controls the gas supply 20 and the plasma generator 12 to etch the substrate W with the first plasma.

In Step ST3, the substrate W is etched with a second plasma generated from the second process gas different from the first process gas. The second process gas may contain the same type of gas as the first process gas. In this case, the flow rate of at least one gas contained in the second process gas is different from the flow rate of at least one gas contained in the first process gas. By etching the first region R1, a recess corresponding to the opening OP1 of the mask MK can be formed in the first region R1. By etching the second region R2, a recess corresponding to the opening OP2 of the mask MK can be formed in the second region R2.

The second process gas contains a Cₓ₁H_{y1}F_{z1} (x1 is an integer of 2 or more, y1 and z1 are integers of 1 or more) gas containing an unsaturated bond. An example of the Cₓ₁H_{y1}F_{z1} gas may be the same as an example of the Cₓ₂H_{y2}F_{z2} gas.

The second process gas may further contain a Cᵥ₂F_{w2} (v2 is an integer of 2 or more, and w2 is an integer of 1 or more) gas containing an unsaturated bond. An example of the Cᵥ₂F_{w2} gas may be the same as the example of the Cᵥ₁F_{w1} gas.

The second process gas may contain a C₃F₆ gas as the Cᵥ₂F_{w2} gas and a C₃H₂F₄ gas as the Cₓ₁H_{y1}F_{z1} gas. A ratio RT2 of the flow rate of the Cᵥ₂F_{w2} gas to the flow rate of the Cₓ₁H_{y1}F_{z1} gas may be less than 1. The ratio RT1 of the flow rate in Step ST2 may be more than the ratio RT2 of the flow rate in Step ST3. The flow rate of the Cᵥ₂F_{w2} gas in Step ST3 may be less than the flow rate of the Cᵥ₁F_{w1} gas in Step ST2. The flow rate of the Cₓ₁H_{y1}F_{z1} gas in Step ST3 may be more than the flow rate of the Cₓ₂H_{y2}F_{z2} gas in Step ST3.

The second process gas may further contain an oxygen-containing gas. An example of the oxygen-containing gas contained in the second process gas may be the same as an example of the oxygen-containing gas contained in the first process gas. The second process gas may further contain an inert gas. An example of the inert gas contained in the second process gas may be the same as an example of the inert gas contained in the first process gas.

The second plasma may be generated at a second pressure. The second pressure may be the pressure in the plasma processing chamber 10. The first pressure in the plasma processing chamber 10 in Step ST2 may be greater than the second pressure inside the plasma processing chamber 10 in Step ST3. A second radio frequency power may be supplied to generate the second plasma. The second radio frequency power may be an RF power HF applied to an upper electrode of the plasma processing apparatus 1. In Step ST3, bias power LF may be applied to electrodes in a body 111 of the substrate support 11. The bias power LF may be 10 kW or more.

In Step ST3, both the RF power HF and the bias power LF may be supplied periodically. The period during which the RF power HF is supplied may be synchronized with the period during which the bias power LF is supplied. The range of the frequency for defining the period of supplying the RF power HF in Step ST3 may be the same as the range of the frequency for defining the period of supplying the RF power HF in Step ST2. In this case, the range of the Duty ratio indicating the ratio of the supply time of the RF power HF within one period in Step ST3 may be the same as the range of the Duty ratio indicating the ratio of the supply time of the RF power HF within one period in Step ST2.

The processing time of Step ST3 may be 5 seconds or greater and 50 seconds or smaller. The processing time of Step ST2 may be longer than the processing time of Step ST3. The ratio of the processing time of Step ST2 to the processing time of Step ST3 may be more than 1 and 3 or less.

Step ST3 may be performed as follows. First, the gas supply 20 supplies the second process gas into the plasma processing chamber 10. Then, the plasma generator 12 generates the second plasma from the second process gas in the plasma processing chamber 10. The controller 2 controls the gas supply 20 and the plasma generator 12 to etch the substrate W with the second plasma.

In Step ST4, Step ST2 and Step ST3 are repeated alternately. Step ST4 may be ended when the number of times of performing each of Steps ST2 and ST3 reaches a threshold value.

In the substrate W after the method MT has been applied, as illustrated in FIG. 5, a recess RS1 is formed in the first region R1, and a recess RS2 is formed in the second region R2. Each of the bottom of the recess RS1 and the bottom of the recess RS2 may reach the underlying region UR. Each of the recesses RS1 and RS2 may be a contact hole or a trench. The aspect ratio of the recess RS1 and the aspect ratio of the recess RS2 may be equal to or more than 10. In the present disclosure, an aspect ratio ASP1 of the recess RS1 is calculated by Expression (1) as follows.

ASP1=1000×NCD/NHD (1)

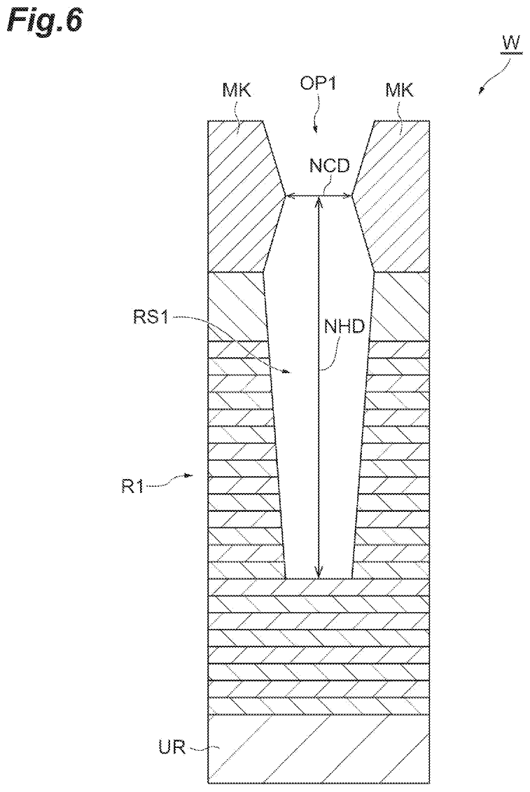

NCD in Expression (1) represents the minimum dimension of the opening OP1, as illustrated in FIG. 6. The opening OP1 has the minimum dimension at the neck of the mask MK. NHD in Expression (1) represents the distance from the position at which the opening OP1 has the minimum dimension to the bottom of the recess RS1 in the direction perpendicular to the main surface of the substrate W, as illustrated in FIG. 6. Thus, the shallower the recess RS1, the more the aspect ratio ASP1. An aspect ratio ASP2 of the recess RS2 is also calculated by the same expression as the aspect ratio ASP1 of the recess RS1.

According to the method MT, it is possible to improve the etching selectivity of the first region R1 and the second region R2 with respect to the mask MK. Although the mechanism is considered as follows, the mechanism is not limited to this. In Steps ST2 and ST3, higher-order radicals are generated from unsaturated bonds contained in the first process gas and the second process gas, respectively. Since the higher-order radicals have high molecular weights, so the higher-order radicals tend to form a deposited film on the surface of the mask MK. Since the mask MK is protected by the deposited film, it is possible to improve the etching selectivity of the first region R1 and the second region R2 with respect to the mask MK.

Furthermore, according to the method MT, it is possible to not only suppress bowing (abnormal shape) of the side wall of the recess RS1 formed in the first region R1, but also to greatly suppress bowing of the side wall of the recess RS2 formed in the second region R2. Although the mechanism is considered as follows, the mechanism is not limited to this. First, the amount of radicals per unit flow rate, which are generated from the Cᵥ₁F_{w1} gas and the Cₓ₁H_{y1}F_{z1} gas, is more than the amount of radicals per unit flow rate, which are generated from a gas that does not contain the unsaturated bonds such as CH₂F₂ gas. Furthermore, the hydrofluorocarbon gas can more effectively suppress the bowing of the side wall of the recess RS2 than the bowing of the side wall of the recess RS1. In Step ST2, radicals generated from the Cᵥ₁F_{w1} gas go into the recesses RS1 and RS2 to form protective films on the side walls of the recesses RS1 and RS2. When the Cᵥ₁F_{w1} gas is used, the thickness of the protective film formed on the side wall of the recess RS1 is more than the thickness of the protective film formed on the side wall of the recess RS2. Thus, it is possible to suppress bowing of the side wall of the recess RS1. In Step ST3, radicals generated from the Cₓ₁H_{y1}F_{z1} gas go into the recesses RS1 and RS2 to form protective films on the side walls of the recesses RS1 and RS2. When the Cₓ₁H_{y1}F_{z1} gas is used, the thickness of the protective film formed on the side wall of the recess RS2 is more than the thickness of the protective film formed on the side wall of the recess RS1. Thus, it is possible to suppress bowing of the side wall of the recess RS2. Furthermore, when the Cᵥ₁F_{w1} gas (for example, C₃F₆ gas) is used in Step ST2, the openings OP1 and OP2 of the mask MK are less likely to be closed. As a result, the amount of radicals transported into the recesses RS1 and RS2 increases.

When the ratio RT1 of the flow rate in Step ST2 is more than the ratio RT2 of the flow rate in Step ST3, the second region R2 can be preferentially etched over the first region R1 in the Step ST2. This is because fluorocarbon has an etching rate with respect to a silicon oxide film, which is higher than an etching rate with respect to a silicon nitride film. In Step ST3, the first region R1 can be preferentially etched over the second region R2. This is because hydrofluorocarbon has an etching rate with respect to a silicon nitride film, which is higher than an etching rate with respect to a silicon oxide film. Thus, it is possible to control the depth of the recess RS1 formed in the first region R1 and the depth of the recess RS2 formed in the second region R2 independently of each other. Therefore, it is possible to reduce the difference between the depth of the recess RS1 and the depth of the recess RS2.

When the method MT includes Step ST4, it is possible to increase the depth of the recess RS1 and the depth of the recess RS2.

When the Cᵥ₁F_{w1} gas contains a fluoromethyl group, lower-order radicals are generated from the fluoromethyl group in Step ST2. Similarly, when the Cₓ₁H_{y1}F_{z1} gas contains a fluoromethyl group, lower-order radicals are generated from the fluoromethyl group in Step ST3. Since the lower-order radicals have low molecular weights, the lower-order radicals can go deep into the recesses RS1 and RS2 formed by etching. Thus, it is possible to form the deep recesses RS1 and RS2. Further, since many lower-order radicals are supplied into the recesses RS1 and RS2, it is possible to increase the etching rate of the first region R1 and the second region R2. Furthermore, since a polymer film is less likely to be formed on the shoulders of the side walls of the recesses RS1 and RS2, it is possible to suppress the clogging of the recesses RS1 and RS2 by the polymer film.

Although the various exemplary embodiments have been described above, various additions, omissions, substitutions, and changes may be made without being limited to the exemplary embodiments described above. Other embodiments can be formed by combining elements in different embodiments.

Various experiments performed for evaluating the method MT are described below. The experiments described below do not limit the present disclosure.

First Experiment

In a first experiment, a substrate W was on the substrate support 11 of the plasma processing chamber 10 in the plasma processing apparatus 1 (Step ST1). The substrate W has the structure illustrated in FIG. 4. A mask MK contains amorphous carbon.

Then, the substrate W was etched with first plasma generated from a first process gas that contains a C₃F₆ gas containing a carbon double bond, a C₃H₂F₄ gas containing a carbon double bond, and an O₂ gas (Step ST2). The ratio RT1 of the flow rate of C₃F₆ gas to the flow rate of the C₃H₂F₄ gas in Step ST2 was 1.01.

Then, the substrate W was etched with second plasma generated from a second process gas that contains a C₃F₆ gas containing a carbon double bond, a C₃H₂F₄ gas containing a carbon double bond, and an O₂ gas (Step ST3). The ratio RT2 of the flow rate of the C₃F₆ gas to the flow rate of the C₃H₂F₄ gas in Step ST3 was 0.98. The pressure in the plasma processing chamber 10 in Step ST3 is lower than the pressure in the plasma processing chamber 10 in Step ST2. The processing time of Step ST3 is shorter than the processing time of Step ST2. The ratio of the processing time of Step ST2 to the processing time of Step ST3 was 2.

Then, Step ST2 and Step ST3 were repeated alternately (Step ST4). As a result, a recess RS1 was formed in the first region R1, and a recess RS2 was formed in the second region R2.

Second Experiment

The same method as the method of the first experiment was performed except that the process gases in Steps ST2 and ST3 were changed. In Step ST2, instead of the first process gas, a process gas containing a C₄F₆ gas, a C₄F₈ gas containing no unsaturated bond, a CH₂F₂ gas, a krypton gas, and an O₂ gas was used. In Step ST3, instead of the second process gas, a process gas containing a C₄F₆ gas, a C₄F₈ gas containing no unsaturated bond, a CH₂F₂ gas, a krypton gas, and an O₂ gas was used.

The ratio of the total flow rate of the C₄F₆ gas and the C₄F₈ gas to the flow rate of the CH₂F₂ gas in Step ST2 was 1.0. The ratio of the total flow rate of the C₄F₆ gas and the C₄F₈ gas to the flow rate of the CH₂F₂ gas in Step ST3 was 1.0.

Etching Selectivity

The etching selectivity of the first region R1 and the second region R2 with respect to the mask MK was calculated. The etching selectivity is the etching amount of the first region R1 or the second region R2 with respect to the etching amount of the mask MK. Assuming that the etching selectivity of the first region R1 in the second experiment was 1, the etching selectivity of the first region R1 in the first experiment was 4.89. Assuming that the etching selectivity of the second region R2 in the second experiment was 1, the etching selectivity of the second region R2 in the first experiment was 5.48. Therefore, the etching selectivity in the first experiment was improved as compared with the second experiment.

Etching Rate

The etching rates of the first region R1 and the second region R2 were calculated. Assuming that the etching rate of the first region R1 in the second experiment was 1, the etching rate of the first region R1 in the first experiment was 1.09. Assuming that the etching rate of the second region R2 in the second experiment was 1, the etching rate of the second region R2 in the first experiment was 1.09. Therefore, the etching rate in the first experiment was improved as compared with the second experiment.

Bowing

Due to the occurrence of bowing, the dimensions of the recesses RS1 and RS2 are increased in parts of the side walls of the recess RS1 and the recess RS2. The maximum value of each of the dimensions of the recesses RS1 and RS2 was set as the bowing dimension. A ratio B/D of the bowing dimension to the depths of the recesses RS1 and RS2 was calculated for the recesses RS1 and RS2. Assuming that the ratio B/D of the recess RS1 in the second experiment was 1, the ratio B/D of the recess RS1 in the first experiment was 0.95. Assuming that the ratio B/D of the recess RS2 in the second experiment was 1, the ratio B/D of the recess RS2 in the first experiment was 0.89. Thus, it is possible to suppress the occurrence of bowing in the first experiment, as compared with the second experiment.

Etching conditions were selected so that the bowing dimension of the recess RS1 in the second experiment was substantially the same as the bowing dimension of the recess RS1 in the first experiment. Assuming that the bowing dimension of the recess RS1 in the second experiment was 1, the bowing dimension of the recess RS2 in the second experiment was 1.51, and the bowing dimension of the recess RS2 in the first experiment was 1.40. Therefore, in the first experiment, it is possible to suppress not only the bowing of the side wall of the recess RS1 but also to greatly suppress the bowing of the side wall of the recess RS2.

Effects of Repetition

In the first experiment, the openings OP1 and OP2 of the mask MK are less likely to be closed in Steps ST2 and ST3, as compared with the second experiment. Therefore, when Steps ST2 and ST3 are repeated alternately in Step ST4, the effect of increasing the etching rate and the effect of suppressing the bowing, as described above, are significantly enhanced.

Cost

Also, since the krypton gas is not required in the first experiment, it is possible to reduce the cost as compared with the second experiment.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended be limiting, with the true scope and spirit being indicated by the following claims.

What is claimed is:

1. An etching method comprising:
(a) providing a substrate on a substrate support in a chamber, the substrate including a first region having a multilayer film in which a silicon oxide film and a silicon nitride film are alternately stacked, a second region having a single-layer silicon oxide film, and a mask on the first region and the second region;
(b) etching the substrate with a first plasma generated from a first process gas; and
(c) etching the substrate with a second plasma generated from a second process gas different from the first process gas,
wherein the first process gas contains a Cᵥ₁F_{w1} (v1 is an integer of 2 or more, and w1 is an integer of 1 or more) gas containing an unsaturated bond, and
the second process gas contains a Cₓ₁H_{y1}F_{z1} (x1 is an integer of 2 or more, and y1 and z1 are integers of 1 or more) gas containing an unsaturated bond.

2. The etching method according to claim 1, further comprising:
(d) repeating (b) and (c) alternately.

3. The etching method according to claim 1,
wherein the first process gas further contains a Cₓ₂H_{y2}F_{z2} (x2 is an integer of 2 or more, and y2 and z2 are integers of 1 or more) gas containing an unsaturated bond,
the second process gas further contains a Cᵥ₂F_{w2} (v2 is an integer of 2 or more, and w2 is an integer of 1 or more) gas containing an unsaturated bond, and
a ratio of a flow rate of the Cᵥ₁F_{w1} gas to a flow rate of the Cₓ₂H_{y2}F_{z2} gas is greater than a ratio of a flow rate of the Cᵥ₂F_{w2} gas to a flow rate of the Cₓ₁H_{y1}F_{z1} gas.

4. The etching method according to claim 3,
wherein the ratio of the flow rate of the Cᵥ₁F_{w1} gas to the flow rate of the Cₓ₂H_{y2}F_{z2} gas is 1 or more and 2 or less.

5. The etching method according to claim 3,
wherein the ratio of the flow rate of the Cᵥ₂F_{w2} gas to the flow rate of the Cₓ₁H_{y1}F_{z1} gas is less than 1.

6. The etching method according to claim 1,
wherein the Cᵥ₁F_{w1} gas contains a fluoromethyl group.

7. The etching method according to claim 6,
wherein the Cᵥ₁F_{w1} gas contains at least one of C₄F₈ or C₃F₆.

8. The etching method according to claim 1,
wherein the Cₓ₁H_{y1}F_{z1} gas contains a fluoromethyl group.

9. The etching method according to claim 8,
wherein the Cₓ₁H_{y1}F_{z1} gas contains at least one of C₃H₂F₄ or C₄H₂F₆.

10. The etching method according to claim 1,
wherein the Cᵥ₁F_{w1} gas contains C₃F₆, and
the Cₓ₁H_{y1}F_{z1} gas contains C₃H₂F₄.

11. The etching method according to claim 1,
wherein a pressure in the chamber in (b) is higher than a pressure in the chamber in (c).

12. The etching method according to claim 1,
wherein a processing time of (b) is longer than a processing time of (c).

13. The etching method according to claim 12,
wherein a ratio of the processing time of (b) to the processing time of (c) is more than 1 and 3 or less.

14. The etching method according to claim 1,
wherein an aspect ratio of a recess formed in the first region and an aspect ratio of a recess formed in the second region in the substrate after the etching method has been applied are equal to or more than 10.

15. The etching method according to claim 1,
wherein at least one of the first process gas or the second process gas further contains an oxygen-containing gas.

16. The etching method according to claim 1,
wherein at least one of the first process gas or the second process gas further contains an inert gas.

17. The etching method according to claim 1,
wherein the mask contains at least one of carbon or boron.

18. A plasma processing apparatus comprising:
a chamber;
a substrate support for supporting a substrate in the chamber, the substrate including a first region having a multilayer film in which a silicon oxide film and a silicon nitride film are alternately stacked, a second region having a single-layer silicon oxide film, and a mask on the first region and the second region;
a gas supply configured to supply a first process gas and a second process gas different from the first process gas into the chamber;
a plasma generator configured to generate a first plasma and a second plasma from the first process gas and the second process gas in the chamber, respectively; and
a controller,
wherein the first process gas contains a Cᵥ₁F_{w1} (v1 is an integer of 2 or more, and w1 is an integer of 1 or more) gas containing an unsaturated bond,
the second process gas contains a Cₓ₁H_{y1}F_{z1} (x1 is an integer of 2 or more, and y1 and z1 are integers of 1 or more) gas containing an unsaturated bond, and
the controller is configured to control the gas supply and the plasma generator to
etch the substrate with the first plasma, and
etch the substrate with the second plasma.
